(19) United States
(12) Patent Application Publication
(10) Pub. No.: US 2026/0309978 A1
(43) Pub. Date: Oct. 8, 2026

(54) MICROELECTROMECHANICAL MIRROR, METHOD OF OPERATING A MICROELECTROMECHANICAL MIRROR, PROJECTION DEVICE AND USE OF A MICROELECTROMECHANICAL MIRROR

(71) Applicant: TDK Electronics AG, Muenchen (DE)

(72) Inventors: Matthias Wulf, Graz (AT); Franz Rinner, Frauental an der Laßnitz (AT)

(21) Appl. No.: 19/472,076

(22) PCT Filed: Feb. 20, 2024
(86) PCT No.: PCT/EP2024/054217

§ 371 Date: Oct. 2, 2025

(30) Foreign Application Priority Data
Apr. 11, 2023 (DE) 10 2023 109 108.5

(51) Int. Cl. G02B 26/08

(52) U.S. Cl. CPC G02B 26/0858

(57) ABSTRACT

In an embodiment a microelectromechanical mirror includes a mirror element and a torsional suspension, which surrounds the mirror element and which is connected to the mirror element via two first torsion spring elements.

### CROSS-REFERENCE TO RELATED APPLICATIONS

This patent application is a national phase filing under section 371 of PCT/EP2024/054217, filed Feb. 20, 2024, which claims the priority of German patent application no. 102023109108.5, filed Apr. 11, 2023, each of which is incorporated herein by reference in its entirety.

### TECHNICAL FIELD

A microelectromechanical mirror, a method of operating a microelectromechanical mirror and a projection device are specified herein.

### BACKGROUND

Microelectromechanical mirrors are used, for example, in laser projectors for the targeted deflection of a laser beam in order to display static or moving images. For example, laser projectors are used in the automotive sector to project information onto a road surface, in HUD (head up display) systems for matrix illumination or for LIDAR (light detection and ranging) applications. In particular, this requires a high depth of field, which laser projectors can provide. Laser projectors are also used, for example, as hologram projectors, in VR glasses (virtual reality) or AR glasses (augmented reality). Here, for example, the deflected laser beam is coupled into a waveguide glass. The direction and not the position of the laser beam determines the position of the pixel for the viewer, so that no additional optics are required.

Laser projectors that are insensitive to vibrations and can be manufactured cost-effectively are particularly advantageous for mobile applications, for example in the automotive sector and for VR or AR glasses. For example, a laser projector has a microelectromechanical mirror that can be rotated in two directions and deflects a time-modulated laser beam to generate an image in the far field. In particular, the projected image is always in focus for a viewer and an eye of the viewer does not need to be accommodated. For example, document JP 2008-20701 A describes a two-dimensional optical scanner. Document JP 6 506 212 B2 describes an optical deflector. Document U.S. Pat. No. 10,371,940 B2 describes a device for driving a mirror and an associated operating method. Document DE 10 2021 116 165 B3 describes a Lissajous microscanner.

### SUMMARY

Embodiments provide a microelectromechanical mirror that has a particularly compact design. Further embodiments provide a method of operating such a microelectromechanical mirror. Yet other embodiments provide a projection device with a microelectromechanical mirror that has a particularly compact design.

According to at least one embodiment, the microelectromechanical mirror comprises a mirror element. In particular, the mirror element has a main extension plane. For example, the mirror element has a circular, oval, square, rectangular or polygonal shape in plan view of the main extension plane. The mirror element comprises, for example, a substrate with a reflective layer applied to it. For example, the substrate comprises silicon or consists of silicon. Alternatively or additionally, the substrate may comprise diamond, cubic boron nitride (BN), silicon nitride (SiN), or boron, or consist of at least one of these materials. For example, the reflective layer comprises a metal or consists of a metal.

In particular, the reflective layer is configured for reflecting and/or deflecting electromagnetic radiation in a spectral range between infrared and ultraviolet light. The reflective layer extends, in particular, in a plane which corresponds to the main extension plane of the mirror element. Here and in the following, the main extension plane is defined in relation to a rest position of the mirror element.

According to at least one further embodiment, the microelectromechanical mirror comprises a torsional suspension which surrounds the mirror element and is connected to the mirror element via two first torsion spring elements. For example, the mirror element is arranged in a center of the torsional suspension. In particular, the torsional suspension surrounds the mirror element in the main extension plane of the mirror element in a resting state of the mirror element. The torsional suspension comprises, for example, a substrate having a form that is ring-shaped in the main extension plane, in the center of which the mirror element is arranged. For example, the substrate comprises silicon or consists of silicon. During operation of the microelectromechanical mirror, in particular when the mirror element is moved, the main extension plane of the mirror element can be twisted in relation to the torsional suspension.

In particular, each of the first torsion spring elements comprises a torsion beam or consists of a torsion beam. For example, the torsion spring elements comprise a substrate comprising silicon or consisting of silicon, for example. The torsion spring elements each have, for example, an elongated, beam-like shape with a rotation axis that in particular corresponds to a longitudinal direction of the respective torsion spring element. For example, during operation a torsional moment acts on the torsion spring elements in relation to the rotation axis, causing the torsion spring elements to twist around their respective rotation axis. In particular, this causes a restoring torsional moment to build up in the torsion spring elements.

The rotation axes of the two first torsion spring elements are preferably aligned along a common first rotation axis. In other words, the two first torsion spring elements have a common first rotation axis about which they twist during operation. In particular, the mirror element is rotatable about the first rotation axis relative to the torsional suspension at least within a first angular range.

For example, the mirror element, the torsional suspension and the first torsion spring elements comprise the same substrate. In other words, the aforementioned elements are integrally formed and/or monolithically integrated.

According to at least one further embodiment, the microelectromechanical mirror comprises a piezoelectric drive ring which surrounds the torsional suspension and is connected to the torsional suspension via two second torsion spring elements. For example, the torsional suspension is arranged in the center of the drive ring. In particular, the drive ring is configured for deflecting the mirror element from its rest position during operation of the microelectromechanical mirror. In doing so, the torsional suspension and/or the mirror element is preferably rotated relative to the drive ring. For example, mechanical stresses are generated in the drive ring, which transmit a bending moment and/or a torque to the torsional suspension via the second torsion spring elements.

The drive ring includes, for example, a substrate that comprises silicon or consists of silicon, on which a piezoelectric layer is applied at least in places. In particular, the piezoelectric layer is arranged parallel to the main extension plane of the mirror element.

The piezoelectric layer is arranged, for example, between a first electrode and a second electrode. The piezoelectric layer can comprise one or more piezoelectric materials. For example, the piezoelectric layer comprises a piezoelectric material, such as lead zirconate titanate (PZT), aluminum nitride (AlN), or bismuth ferrate barium titanate (BFO-BT), or consists of such a material. In particular, by applying an electrical voltage to the electrodes, the piezoelectric layer generates the mechanical stresses in the drive ring.

Each of the second torsion spring elements comprises, in particular, a torsion bar or consists of a torsion bar. For example, the torsion spring elements comprise a substrate comprising silicon or consisting of silicon, for example. The torsion spring elements each have, for example, an elongated, beam-like shape with a rotation axis that corresponds in particular to a longitudinal direction of the respective torsion spring element. During operation, for example, a torsional moment acts on the torsion spring elements in relation to the rotation axis, causing the torsion spring elements to twist around their respective rotation axis. In particular, a restoring torsional moment builds up in the torsion spring elements.

The rotation axes of the two second torsion spring elements are preferably aligned along a common second rotation axis. In other words, the two second torsion spring elements have a common second rotation axis about which they twist during operation. In particular, the torsional suspension and thus the mirror element is rotatable about the second rotation axis relative to the drive ring at least within a second angular range. The second rotation axis is, for example, transverse or orthogonal to the first rotation axis.

According to at least one further embodiment of the microelectromechanical mirror, the torsional suspension has an elongated shape with a long axis and a short axis perpendicular thereto. The long axis and the short axis are, for example, symmetry axes of the torsional suspension. In particular, the torsional suspension has a larger spatial extension in the direction of the long axis than in the direction of the short axis. In other words, a diameter of the torsional suspension in the direction of the long axis is larger than a diameter of the torsional suspension in the direction of the short axis. For example, the diameter of the torsional suspension in the direction of the long axis is at least 5% larger, preferably at least 20% larger, and particularly preferably at least 40% larger, than the diameter in the direction of the short axis. The long axis and the short axis lie, for example, in the main extension plane of the mirror element.

The first rotation axis coincides, for example, with the long axis, while the second rotation axis coincides, for example, with the short axis. During operation of the microelectromechanical mirror, the mirror element is therefore at least partially rotatable relative to the drive ring, particularly with respect to the short axis and with respect to the long axis.

Due to the elongated shape of the torsional suspension, at least one oscillation mode of the mirror element and/or of the torsional suspension has, in particular, a lower anharmonicity than a corresponding oscillation mode of a torsional suspension that does not have an elongated shape. Here and in the following, the anharmonicity describes, in particular, a dependence of a resonance frequency of the oscillation mode on an amplitude of the oscillation mode. In other words, the greater the shift of the resonance frequency when the amplitude of the oscillation mode is increased, the greater the anharmonicity.

According to a preferred embodiment, the microelectromechanical mirror comprises:
the mirror element,
the torsional suspension, which surrounds the mirror element and is connected to the mirror element via the two first torsion spring elements.

According to a further preferred embodiment, the microelectromechanical mirror comprises:
the mirror element,
the torsional suspension, which surrounds the mirror element and is connected to the mirror element via the two first torsion spring elements,
the piezoelectric drive ring, which surrounds the torsional suspension and is connected to the torsional suspension via the two second torsion spring elements, wherein
the torsional suspension has an elongated shape with a long axis and a short axis perpendicular thereto.

In particular, the microelectromechanical mirror described herein is based on the idea of exciting two different oscillation modes, in which the mirror element rotates about one of the two rotation axes, respectively, via just a single drive ring. This makes the microelectromechanical mirror particularly compact. Furthermore, an oscillation mode in which the mirror element rotates about the long axis advantageously exhibits a particularly low anharmonicity due to the elongated shape of the torsional suspension.

According to at least one further embodiment of the microelectromechanical mirror, the first torsion spring elements are arranged along the long axis. In particular, the first rotation axis or a torsion axis of the first torsion spring elements is aligned along the long axis of the torsional suspension.

According to at least one further embodiment of the microelectromechanical mirror, the second torsion spring elements are arranged along the short axis. In particular, the second rotation axis or a torsion axis of the second torsion spring elements is aligned along the short axis of the torsional suspension.

According to at least one further embodiment of the microelectromechanical mirror, the two first torsion spring elements are arranged on opposite sides of the mirror element. This improves, for example, the mechanical stability of the suspension of the mirror element.

According to at least one further embodiment of the microelectromechanical mirror, the two second torsion spring elements are arranged on opposite sides of the torsional suspension. This improves, for example, the mechanical stability of the suspension of the torsional suspension.

According to at least one further embodiment of the microelectromechanical mirror, the torsional suspension has an elliptical ring shape or the shape of an indented oval ring. For example, an outer circumference of the torsional suspension has the shape of an ellipse or an indented oval. For example, a large semiaxis of the ellipse corresponds to the long axis of the torsional suspension, while a small semiaxis of the ellipse corresponds to the short axis of the torsional suspension. For example, the long axis and the short axis of the torsional suspension correspond to two axes of symmetry of the indented oval.

In the indented oval, for example, a distance between the circumference of the torsional suspension and the long axis has a local minimum at the short axis. In particular, the distance from the long axis corresponds to a distance in a direction perpendicular to the long axis. In other words, the circumference of the torsional suspension has a constriction at the short axis. For example, the circumference of the torsional suspension has the shape of a Cassini curve.

According to at least one further embodiment of the microelectromechanical mirror, the torsional suspension has no piezoelectric drive elements and/or the torsional suspension consists of the substrate. For example, the torsional suspension is a passive element. In particular, the torsional suspension is not configured for converting electrical energy into kinetic energy. By contrast, the drive ring is an active element and is configured for converting electrical energy into kinetic energy.

For example, the torsional suspension consists of the substrate. In one embodiment, only one sensor element or several sensor elements can be applied to the substrate of the torsional suspension, whereby the sensor element or the sensor elements can be piezoelectric elements, and whereby no drive element is arranged on the torsional suspension. For example, the sensor element is configured for detecting a state of movement of the mirror element. The sensor element is not intended for deflecting the mirror element from its rest position.

According to at least one further embodiment of the microelectromechanical mirror, the mirror element and the first torsion spring elements are connected to each another via a connection element. In particular, the connection element is configured for mechanically connecting the mirror element with the first torsion spring elements. In particular, the connection element is designed such that the main extension plane of the mirror element bends or deforms as little as possible when the mirror element oscillates about the two axes of rotation. As a result, imaging errors can be reduced during operation of the microelectromechanical mirror. For example, the connection element reduces the transmission of torsion from the first torsion spring elements to the mirror element. In particular, the connection element includes a substrate that comprises silicon or consists of silicon, for example.

According to at least one further embodiment of the microelectromechanical mirror, the connection element has a circular ring shape and is connected to the mirror element via two suspension points. In particular, the mirror element is arranged in the center of the connection element. The connection element extends, for example, in the main extension plane of the mirror element.

According to at least one further embodiment of the microelectromechanical mirror, the two suspension points are arranged on opposite sides of the mirror element along the short axis. In particular, the suspension points are rotated by 90° relative to the first rotation axis of the first torsion spring elements.

According to at least one further embodiment of the microelectromechanical mirror, the connection element comprises two separate arc-shaped segments that are connected to one of the two first torsion spring elements, respectively.

According to at least one further embodiment of the microelectromechanical mirror, each of the arc-shaped segments is connected to the mirror element via two suspension points. The suspension points are arranged, for example, at the respective ends of the arc-shaped segments. The first torsion spring elements are connected to the respective arc-shaped segment between the two suspension points, for example.

According to at least one further embodiment of the microelectromechanical mirror, the drive ring is circular ring-shaped. According to a further embodiment of the microelectromechanical mirror, the drive ring is arranged in the main extension plane of the mirror element in the rest position. In particular, the torsional suspension and the mirror element are arranged in the center of the drive ring.

According to at least one further embodiment of the microelectromechanical mirror, the drive ring is connected to a frame via two third torsion spring elements. For example, the frame completely surrounds the drive ring in the main extension plane of the mirror element. In particular, the frame includes a substrate that comprises silicon or consists of silicon, for example. The third torsion spring elements have, for example, a similar or identical structure to the second torsion spring elements, or are of formed in the same or in a similar manner as the second torsion spring elements.

For example, electrical contact terminals are arranged on the frame for an external electrical contacting of the microelectromechanical mirror. The electrical contact terminals are electrically connected to the piezoelectric drive ring via conductor tracks, for example. In particular, the conductor tracks are arranged on the third torsion spring elements. Alternatively or additionally, the piezoelectric drive ring can be electrically connected to the electrical contact points via bond wires. Due to the low movement of the drive ring, the mechanical load on the bond wires is particularly low.

According to at least one further embodiment of the microelectromechanical mirror, the two third torsion spring elements are arranged on opposite sides of the drive ring along the short axis. For example, both the second torsion spring elements and the third torsion spring elements are aligned along the short axis.

According to at least one further embodiment of the microelectromechanical mirror, the mirror element, the torsional suspension, the drive ring, the frame and the torsion spring elements are formed as a one-piece component. In other words, the mirror element, the torsional suspension, the drive ring, the frame and the torsion spring elements are monolithically integrated and/or formed from a common substrate. For example, the substrate is monocrystalline. In addition, the connection element between the first torsion spring elements and the mirror element can also be formed in one piece with the above-mentioned elements. For example, during the manufacturing of the microelectromechanical mirror, the common substrate is structured in such a way that the above-mentioned elements are formed in the common substrate.

According to at least one further embodiment of the microelectromechanical mirror, all elements of the one-piece component comprise a common substrate that has a constant thickness. Here and in the following, the thickness specifies a spatial extension of the substrate in a direction perpendicular to the main extension plane. In particular, this simplifies a manufacturing process of the microelectromechanical mirror. For example, the thickness of the substrate is between 20 μm and 500 μm. Alternatively, the substrate can also have areas with different thicknesses. For example, the substrate in the area of the frame can have a larger thickness in order to improve the mechanical stability of the microelectromechanical mirror, while the substrate in the area of the drive ring, for example, has a smaller thickness and thus a greater flexibility and/or a lower inertia. The substrate in the region of the mirror element can have a larger thickness compared to the drive ring, for example in order to reduce deformations of the mirror element during operation.

According to at least one further embodiment of the microelectromechanical mirror, a piezoelectric layer is disposed on the drive ring. In particular, the piezoelectric layer is disposed at least in places on a main surface of the drive ring, which is arranged parallel to the main extension plane of the mirror element. For example, the piezoelectric layer comprises PZT, AlN or BFO-BT, or consists of one of these materials. For example, the piezoelectric layer has a thickness of between 0.5 μm and 5 μm.

According to at least one further embodiment of the microelectromechanical mirror, the piezoelectric layer is arranged between a first electrode and a second electrode. In particular, the first and second electrodes are configured for applying an electric voltage to the piezoelectric layer. In particular, applying the electric voltage during operation generates mechanical stresses in the drive ring. The mechanical stresses induce, for example, torsional moments and/or bending moments, which are transmitted to the torsional suspension and/or to the mirror element via the second torsion spring elements.

According to at least one further embodiment of the microelectromechanical mirror, the second electrode comprises a plurality of drive regions that are separated from each other. For example, the second electrode is segmented. In particular, the drive regions can be electrically controlled independently of one another. For example, by applying electrical voltages to different drive regions, different torsional and/or bending moments can be generated in the drive ring, in particular in order to excite different oscillation modes of the torsional suspension and/or of the mirror element.

According to at least one further embodiment of the microelectromechanical mirror, at least one sensor element for determining a deflection and/or a frequency of an oscillation of the mirror element is arranged on the drive ring and/or on the frame.

According to at least one further embodiment of the microelectromechanical mirror, at least one sensor element for determining a deflection and/or a frequency of an oscillation of the mirror element is arranged on the torsional suspension.

In particular, the at least one sensor element can be used to determine an alignment of the mirror element relative to the torsional suspension, the drive ring and/or the frame during operation. The sensor element generates, for example, a time-dependent electrical signal that is, for example, proportional to an instantaneous deflection angle of the mirror element.

For example, the electrical signal from the sensor element can be used to control and/or fine-tune the oscillation frequencies of the mirror element about the two rotation axes. In other words, an actuation signal of the drive ring can be adjusted depending on the measured values determined from the sensor element.

According to at least one further embodiment of the microelectromechanical mirror, the at least one sensor element comprises a piezoelectric layer. According to at least one further embodiment of the microelectromechanical mirror, the piezoelectric layer is arranged between two electrodes. The piezoelectric layer is disposed, for example, on a surface of the torsional suspension that is arranged parallel to the main extension plane of the mirror element. A deflection of the mirror element, for example, generates mechanical tension in the torsional suspension. In particular, this deforms the piezoelectric layer and generates an electrical voltage. For example, this electrical voltage can be read out as an electrical signal from the sensor element.

According to at least one further embodiment of the microelectromechanical mirror, the torsional suspension is configured for linearizing an oscillation mode about the long axis. In other words, the oscillation mode about the long axis has a lower anharmonicity due to the shape of the torsional suspension. For example, the elongated shape of the torsional suspension gives rise to a linearization of the oscillation mode about the long axis. In particular, the oscillation mode about the long axis is a combination of a torsional movement of the mirror element, whereby the first torsion spring elements twist, and a bending movement of the torsional suspension.

In particular, the microelectromechanical mirror described herein is based on the following ideas. Rotary oscillations of the mirror element around the first and second rotation axis are excited resonantly, for example. This results, for example, in so-called Lissajous scanning, in which a laser beam deflected by the mirror element describes a Lissajous figure on a projection surface during operation of the microelectromechanical mirror. By modulating the laser beam in time, for example, a static or moving image can be generated on the projection surface. In particular, for a given image refresh rate and a given image resolution, this places the following requirements on the microelectromechanical mirror:
a diameter of the mirror element determines an aperture and thus a diffraction-limited resolution of individual pixels;
a maximum deflection angle of the mirror element about the first and second rotation axis together with the diameter of the mirror element determines an image resolution, i.e. a number of pixels per direction. For example, the microelectromechanical mirror should achieve an image resolution of at least 1024×768 pixels, preferably at least 720p;
resonance frequencies of oscillation modes, wherein the mirror element oscillates around the first rotation axis or around the second rotation axis, determine an image refresh rate and also influence the image resolution, in particular;
the oscillation modes should bend the mirror element as little as possible during operation such that the reflective layer remains as flat as possible in order to avoid imaging errors, pixel smearing and/or speckle patterns;
the mirror element should oscillate harmonically around the first and second rotation axis to ensure a stable frequency ratio between the frequencies of the oscillations around the two rotation axes;
the resonances of the oscillation modes should have a bandwidth that is not too narrow in order to allow fine adjustment of the frequencies of the oscillations around the first and second axes of rotation during operation;
the microelectromechanical mirror should be as compact as possible;
the microelectromechanical mirror should be as resistant as possible to vibrations during operation; and/or
the microelectromechanical mirror should have the lowest possible power consumption, for example at most 200 mW, preferably at most 100 mW, and particularly preferably at most 50 mW.

The microelectromechanical mirror described herein fulfills at least one, preferably several, and particularly preferably all of the above-mentioned requirements, for example due to at least one, preferably several, and particularly preferably all of the following features:
the oscillation about the short axis is, in particular, a pure torsional oscillation mode, while the oscillation about the long axis is, for example, a modified “rocking” mode, which is a combination of a torsional movement of the mirror element and a bending movement of the torsional suspension, due to the elongated shape of the torsional suspension. In particular, this reduces the anharmonicity of the rocking mode;
for example, all elements of the microelectromechanical mirror have a common substrate with a constant thickness. In other words, all elements of the microelectromechanical mirror have a substrate with the same thickness. This simplifies the manufacturing process of the microelectromechanical mirror. Alternatively, the substrate can also have several areas with different thicknesses;
the resonance frequencies of the two oscillation modes are significantly different and, in particular, outside an audible frequency range. This allows the suspension of the mirror to be optimized for one direction, which can also allow to reduce the thickness of the substrate, for example;
a desired mirror diameter, the shape of the torsional suspension, the desired resonance frequencies and the required flatness of the mirror element determine the thickness of the substrate in combination with the material of the substrate;
a shape and size of the torsional suspension as well as a dimensioning of the first torsion spring elements results from a desired angular range for the rotation about the first rotation axis, a permitted mechanical stress, a desired resonance frequency, as well as a desired linearity or harmonicity of the oscillation mode about the first rotation axis;
the second torsion spring elements are arranged inside the drive ring for rotation about the second rotation axis and are rotated by 90° to the long axis of the torsional suspension. This gives the microelectromechanical mirror a particularly compact design. The dimensioning of the second torsion spring elements results from a desired angular range for the rotation about the second rotation axis, a permitted mechanical stress and a desired resonance frequency of the oscillation mode around the second rotation axis;
conductor tracks for electrical contacting of the piezoelectric layer of the drive ring can be arranged on the third torsion spring elements, which do not move or hardly move at all during operation.

According to at least one embodiment, the microelectromechanical mirror is used for projecting information onto a surface, for head-up displays, for matrix illumination, for LIDAR applications, for hologram projectors, for VR glasses or for AR glasses.

Furthermore, a method of operating a microelectromechanical mirror is disclosed. In particular, the method is applicable for operating the microelectromechanical mirror described herein. All features of the microelectromechanical mirror are also disclosed for the method of operating a microelectromechanical mirror, and vice versa.

According to at least one embodiment of the method of operating a microelectromechanical mirror, the mirror element is set into a first oscillation mode by means of a first electrical alternating current signal with a first frequency acting on first drive regions of the drive ring.

According to at least one further embodiment of the method, the torsional suspension is set into a second oscillation mode by means of a second electrical alternating current signal with a second frequency acting on second drive regions of the drive ring. In particular, the torsional suspension oscillates together with the mirror element in the second oscillation mode.

In particular, the first and second drive regions correspond to drive regions of the second electrode that is configured for electrically contacting the piezoelectric layer of the drive ring.

According to at least one further embodiment of the method, the first oscillation mode comprises a rotation of the mirror element about the long axis.

According to at least one further embodiment of the method, the second oscillation mode comprises a rotation of the mirror element about the short axis. In particular, the torsional suspension rotates about the short axis together with the mirror element in the second oscillation mode.

According to at least one further embodiment of the method, the first oscillation mode and/or the second oscillation mode are resonantly excited. In particular, the first oscillation mode and the second oscillation mode are excited simultaneously and are superimposed during operation of the microelectromechanical mirror. For example, the first frequency corresponds to a resonance frequency of the first oscillation mode, or deviates from the resonance frequency of the first oscillation mode by at most one bandwidth of a resonance of the first oscillation mode. For example, the second frequency corresponds to a resonance frequency of the second oscillation mode, or deviates from the resonance frequency of the second oscillation mode by at most one bandwidth of a resonance of the second oscillation mode.

According to at least one further embodiment of the method, a movement of the drive ring in the first oscillation mode and/or in the second oscillation mode has an amplitude that is at most one fifth, preferably at most one tenth, of an amplitude of a movement of the mirror element. In other words, the drive ring hardly moves in the first oscillation mode and in the second oscillation mode. For example, the movement of the drive ring is negligibly small compared to the mirror element. This reduces, for example, a damping of the oscillation modes due to air resistance and/or increases an excitation efficiency. For example, a mechanical amplification converts a small distortion of the drive ring into a large deflection of the mirror element. Furthermore, the third torsion spring elements twist little or hardly at all in the first oscillation mode and in the second oscillation mode.

Conductor tracks, which are routed via the third torsion spring elements for electrical contacting of the electrodes of the drive ring, for example, are subjected to little mechanical stress or as little mechanical stress as possible due to the low movement of the drive ring. This increases the lifetime of the microelectromechanical mirror, for example. The electrodes of the drive ring can alternatively or additionally be electrically contacted via bonding wires.

According to at least one further embodiment of the method, a resonance frequency of the first oscillation mode is larger than a resonance frequency of the second oscillation mode by at least a factor of 1.3. Due to the significant difference between the two resonant frequencies, the suspension of the mirror element can, for example, be optimized independently of one another for movement about the two axes of rotation.

According to at least one further embodiment of the method, the resonance frequency of the second oscillation mode is at least 16 kHz, preferably at least 20 kHz. In particular, the resonance frequencies of the first and second oscillation modes are not in the audible range, which means that the microelectromechanical mirror does not generate any disturbing background noise during operation, for example. Furthermore, higher resonance frequencies allow, for example, an increase in image resolution for projection applications.

According to at least one further embodiment of the method, the first oscillation mode and/or the second oscillation mode are operated in a harmonic range. In other words, the first oscillation mode and the second oscillation mode have a low anharmonicity. Thus, a frequency ratio between the first oscillation mode and the second oscillation mode does not change or changes only slightly during operation. In other words, the frequency ratio remains advantageously stable during operation. For example, the frequency ratio between the first oscillation mode and the second oscillation mode changes during operation by at most 5%, preferably by at most 1%, particularly preferably by at most 0.1%.

According to at least one further embodiment of the method, the second oscillation mode is a torsional oscillation of the torsional suspension with the mirror element about the short axis, while the first oscillation mode is a combination of a torsional oscillation of the mirror element about the long axis and a bending movement of the torsional suspension. In particular, the first oscillation mode is a so-called “rocking” mode, in which, for example, one of the two second torsion spring elements is periodically moved in a direction perpendicular to the main extension plane of the mirror element, while the other of the two second torsion spring elements is moved, for example, in antiphase thereto. In particular, this causes the mirror element to oscillate about the long axis.

Further, a projection device is specified. In particular, the projection device comprises the microelectromechanical mirror described herein. All features of the microelectromechanical mirror are also disclosed for the projection device, and vice versa.

According to at least one embodiment, the projection device comprises a laser light source and a microelectromechanical mirror described herein. During operation, the microelectromechanical mirror deflects laser light emitted by the laser light source, for example. Due to the previously described oscillation modes of the mirror element, the deflected laser light can be used, in particular, to scan an image area that can be perceived by an observer. In particular, the microelectromechanical mirror is configured for a Lissajous scanning of the image area.

### BRIEF DESCRIPTION OF THE DRAWINGS

Further advantageous embodiments and further developments of the microelectromechanical mirror, of the method of operating a microelectromechanical mirror and of the projection device become apparent from the exemplary embodiments described in conjunction with the figures below.

FIG. 1 shows a schematic plan view of a microelectromechanical mirror according to a first exemplary embodiment;

FIG. 2 shows a schematic plan view of a microelectromechanical mirror according to a second exemplary embodiment;

FIGS. 3A to 3J show schematic representations of oscillation modes of a microelectromechanical mirror according to the first exemplary embodiment;

FIGS. 4A and 4B show schematic representations of a second oscillation mode of a microelectromechanical mirror according to the first exemplary embodiment;

FIGS. 5A and 5B show schematic representations of a first oscillation mode of a microelectromechanical mirror according to the first exemplary embodiment;

FIG. 6 shows a schematic representation of a deflection of a mirror element and a mechanical stress of a microelectromechanical mirror according to the first exemplary embodiment;

FIG. 7 shows a schematic representation of a deflection of a mirror element of a microelectromechanical mirror according to the first exemplary embodiment;

FIGS. 8A to 8J show schematic representations of oscillation modes of a microelectromechanical mirror according to the second exemplary embodiment;

FIGS. 9A and 9B show schematic representations of a second oscillation mode of a microelectromechanical mirror according to the second exemplary embodiment;

FIGS. 10A and 10B show schematic representations of a first oscillation mode of a microelectromechanical mirror according to the second exemplary embodiment;

FIG. 11 shows a schematic representation of a deflection of a mirror element and a mechanical stress of a microelectromechanical mirror according to the second exemplary embodiment;

FIG. 12 shows a schematic representation of a deflection of a mirror element of a microelectromechanical mirror according to the second exemplary embodiment;

FIG. 13 shows a schematic sectional view of a microelectromechanical mirror according to the second exemplary embodiment; and

FIG. 14 shows a schematic representation of a projection device according to an exemplary embodiment.

Identical, similar or similarly acting elements are provided with the same reference signs in the figures. The figures and the proportions of the elements shown in the figures are not to be regarded as being true to scale. Rather, individual elements may be shown exaggeratedly large or small for better visualization and/or understanding.

### DETAILED DESCRIPTION OF ILLUSTRATIVE EMBODIMENTS

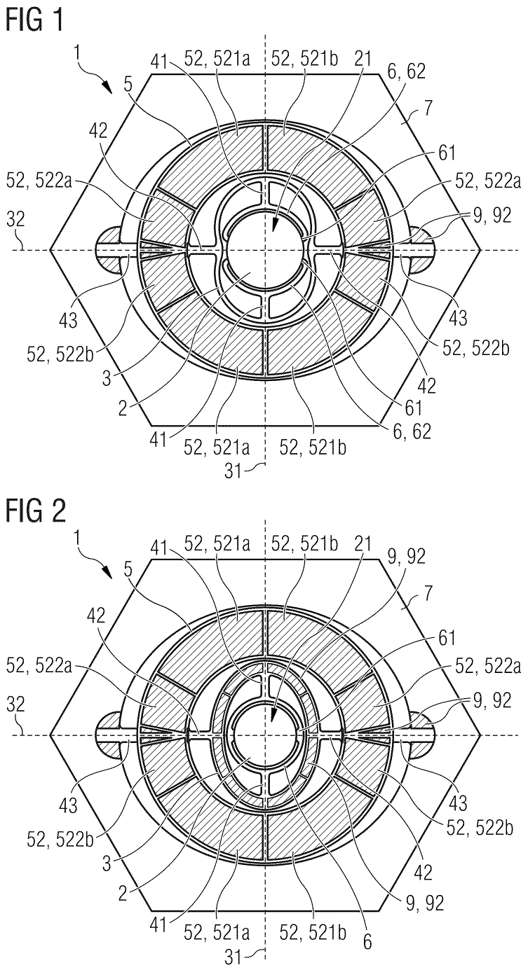

The microelectromechanical mirror 1 according to the first exemplary embodiment in FIG. 1 comprises a mirror element 2, a connection element 6, a torsional suspension 3, a drive ring 5, a frame 7 and two first, second and third torsion spring elements 41, 42 and 43, respectively, which are integrally formed in one piece from a common silicon substrate 8. In particular, FIG. 1 shows a top view of the main extension plane 21 of the mirror element 2.

The mirror element 2 is circular or elliptical and has, for example, a diameter of between 1 mm and 2 mm. A reflective layer 22 is disposed on the main surface 21 of the mirror element 2 (not shown), which comprises a metal, a dielectric mirror or a nano-structured surface and is configured for reflecting electromagnetic radiation in a spectral range between infrared and ultraviolet light.

A connection element 6 mechanically connects the mirror element 2 to two first torsion spring elements 41, which are arranged on opposite sides of the mirror element 2. The connection element 6 comprises two arc-shaped segments 62, each of which is mechanically connected to the mirror element 2 via two suspension points 61 at their ends. The two first torsion spring elements 41 are mechanically connected to one of the segments 61, respectively, in the middle between the two suspension points 61.

The two first torsion spring elements 41 mechanically connect the connection element 6 to the torsional suspension 3. The torsional suspension 3 completely surrounds the mirror element 2 and the connection element 6 in the main extension plane 21, so that the mirror element 2 is arranged in the center of the torsional suspension 3. The torsional suspension 3 has an elongated shape with a long axis 31 and a short axis 32, which are each axes of symmetry of the torsional suspension 3. The diameter of the torsional suspension 3 along the long axis 31 is approximately 50% larger than the diameter of the torsional suspension 3 along the short axis 32. A circumference of the torsional suspension 3 has the shape of an indented or constricted oval. The two first torsion spring elements 41 are arranged along the long axis 31.

The two second torsion spring elements 42 mechanically connect the torsional suspension 3 to the drive ring 5. The two second torsion spring elements 42 are arranged on opposite sides of the torsional suspension 3 along the short axis 32.

The drive ring 5 is circular or elliptical and is mechanically connected to the frame 7 via two third torsion spring elements 43. The torsional suspension 3 is arranged in the center of the drive ring 5. The frame 7 completely surrounds the drive ring 5 in the main extension plane 21. A piezoelectric layer 50 made of PZT (not shown), which is arranged between a first electrode 51 (not shown) and a second electrode 52, is disposed on a main surface of the drive ring 5 that is arranged parallel to the main extension plane 21. The second electrode 52 has separate first drive regions 521a, 521b and second drive regions 522a, 522b.

A first oscillation mode 11 of the microelectromechanical mirror 1 can be excited by applying a temporally oscillating electrical voltage between the first electrode 51 and the first drive regions 521a, 521b of the second electrode 52. By applying a temporally oscillating electrical voltage between the first electrode 51 and the second drive regions 522a, 522b of the second electrode 52, a second oscillation mode 12 of the microelectromechanical mirror 1 can be excited. In particular, the first oscillation mode 11 comprises a rotational oscillation of the mirror element 2 about the long axis 31, while the second oscillation mode 12 comprises, in particular, a rotational oscillation of the mirror element 2 about the short axis 32. In particular, the electrical voltage is applied in the first drive regions 521a and 521b with opposite phase. Similarly, the electrical voltage is applied in the second drive regions 522a and 522b, in particular, with opposite phase.

Sensor elements 9 for determining a deflection and/or a frequency of the oscillation of the mirror element 2 during the operation of the microelectromechanical mirror 1 are arranged both on the drive ring 5 and on the frame 7. The sensor elements 9 comprise a piezoelectric layer 90 (not shown), which is arranged between a first electrode 91 (not shown) and a second electrode 92. In particular, the sensor elements 9 detect mechanical stresses of the microelectromechanical mirror 2 that occur during an oscillation of the mirror element 2 during operation of the microelectromechanical mirror 1.

In particular, the microelectromechanical mirror 1 of the first exemplary embodiment comprises the following features:
thickness of the piezoelectric layer 50, 90:1.7 μm;
thickness of the Si substrate 8: 150 μm, wherein the short axis 32 is aligned along a crystal direction <100> and the long axis 31 is aligned along a crystal direction <010>;
dimensions of the microelectromechanical mirror 1 in the main extension plane 21: 7.65 mm×9.35 mm;
resonance frequency of the first oscillation mode 11: 30.8 kHz;
resonance frequency of the second oscillation mode 12: 20.9 kHz;
maximum deflection angle of the mirror element 2 in the first oscillation mode 11: 16.5°;
maximum deflection angle of the mirror element 2 in the second oscillation mode 12: 11°;
Q-factor of the oscillation modes: 103;
anharmonicity of the first oscillation mode 11: frequency shift of 6 Hz at a deflection angle of 1° to 16.5°;
anharmonicity of the second oscillation mode 12: frequency shift of −1.4 Hz at a deflection angle of 1° to 11°;
sensitivity of the sensor element 9 for the first oscillation mode 11: 0.5 μA/° to 15.0 μA/°;
sensitivity of the sensor element 9 for the second oscillation mode 12: 0.2 μA/° to 1.5 μA/°.

In contrast to the first exemplary embodiment, the microelectromechanical mirror 1 according to the second exemplary embodiment in FIG. 2 comprises a torsional suspension 3 with an elliptical ring shape. Furthermore, additional sensor elements 9 are arranged on a main surface of the torsional suspension 3, which is arranged parallel to the main extension plane 21. The sensor elements 9 comprise a piezoelectric layer 90 (not shown), which is arranged between a first electrode 91 (not shown) and a second electrode 92. The second electrode 92 is segmented, so that the sensor element 9 on the torsional suspension 3 has several readout regions. The additional sensor elements 9 on the torsional suspension 3 can, for example, improve the measurement accuracy of the sensor elements.

In addition, the connection element 6 in the second exemplary embodiment is circular ring-shaped and has two suspension points 61 for the mirror element 2 along the short axis 32.

In particular, the microelectromechanical mirror 1 of the second exemplary embodiment comprises the following features:
thickness of the piezoelectric layer 50, 90: 1.7 μm;
thickness of the Si substrate 8: 50 μm, wherein the short axis 32 is aligned along a crystal direction <100> and the long axis 31 is aligned along a crystal direction <010>;
dimensions of the microelectromechanical mirror 1 in the main extension plane 21: 7.65 mm×9.35 mm;
resonance frequency of the first oscillation mode 11: 20.3 kHz;
resonance frequency of the second oscillation mode 12: 9.2 kHz;
maximum deflection angle of the mirror element 2 in the first oscillation mode 11: 16.5°;
maximum deflection angle of the mirror element 2 in the second oscillation mode 12: 11°;
Q-factor of the oscillation modes: 103;
anharmonicity of the first oscillation mode 11: frequency shift of 184.6 Hz at a deflection angle of 1° to 16.5°;
anharmonicity of the second oscillation mode 12: frequency shift of 21.2 Hz at a deflection angle of 1° to 11°;
sensitivity of the sensor element 9 for the first oscillation mode 11: 0.5 μA/° to 45.2 μA/°;
Sensitivity of the sensor element 9 for the second oscillation mode 12: 0.04 μA/° to 19.2 μA/°.

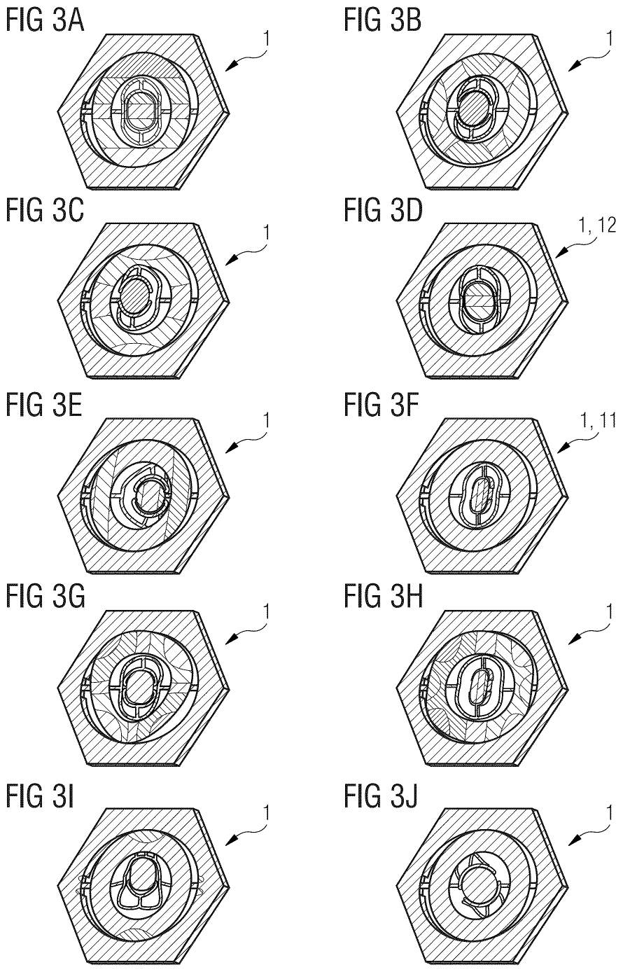

FIGS. 3A to 3J show numerical simulations of different oscillation modes of a microelectromechanical mirror 1 according to the first exemplary embodiment. In particular, a deflection of different elements of the microelectromechanical mirror 1 at a certain point in time is shown exaggeratedly large for better visualization. The resonance frequencies fR of the oscillation modes shown are listed in the following table:

| FIG. | 3A | 3B | 3C | 3D | 3E |
|---|---|---|---|---|---|
| fR [kHz] | 8.66 | 10.74 | 17.22 | 20.86 | 27.47 |
| FIG. | 3F | 3G | 3H | 3I | 3J |
| fR [kHz] | 30.81 | 37.45 | 40.73 | 47.32 | 49.10 |

The oscillation mode in FIG. 3D corresponds to the second oscillation mode 12 of the first exemplary embodiment, in which the mirror element 2 together with the torsional suspension 3 performs a rotational oscillation about the short axis 32.

The oscillation mode in FIG. 3F corresponds to the first oscillation mode 11 of the first exemplary embodiment, in which the mirror element 2 performs a rotational oscillation about the long axis 31, while the torsional suspension 3 performs a bending movement, in particular.

In particular, the resonance frequencies of the various oscillation modes have a large frequency spacing, such that the first and second oscillation modes 11 and 12 can be selectively excited without exciting further parasitic oscillation modes.

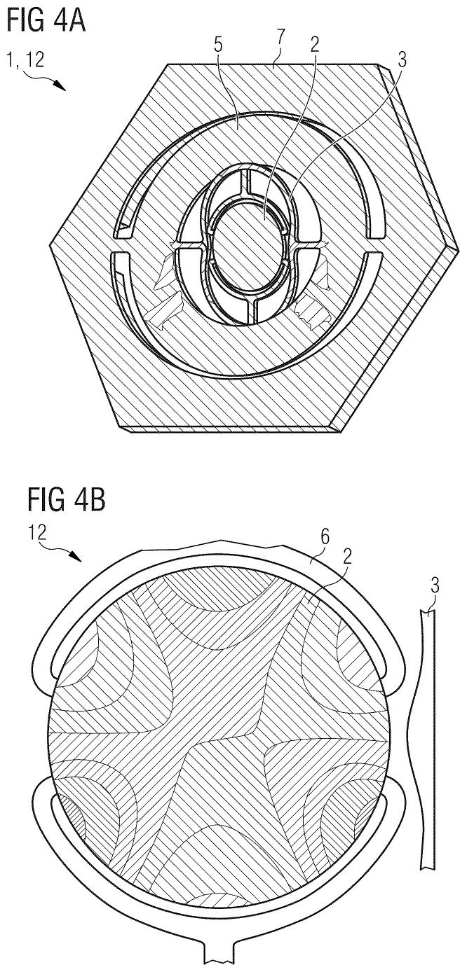

FIG. 4A shows a schematic representation of a tensile stress in a material of a microelectromechanical mirror 1 according to the first exemplary embodiment. In particular, the tensile stress within the microelectromechanical mirror 1 is shown at a maximum deflection angle of the mirror element 2 of 11° about the short axis 32 in the second oscillation mode 12. A maximum tensile stress is approximately 1.7 GPa.

FIG. 4B shows a schematic representation of a deformation of the main extension plane 21 of the mirror element 2 of a microelectromechanical mirror 1 according to the first exemplary embodiment. In particular, the deformation is shown in a direction perpendicular to the main extension plane 21 at a maximum deflection angle of the mirror element 2 of 11° about the short axis 32 in the second oscillation mode 12. A maximum deformation is approximately ±250 nm at the edge of the mirror element 2.

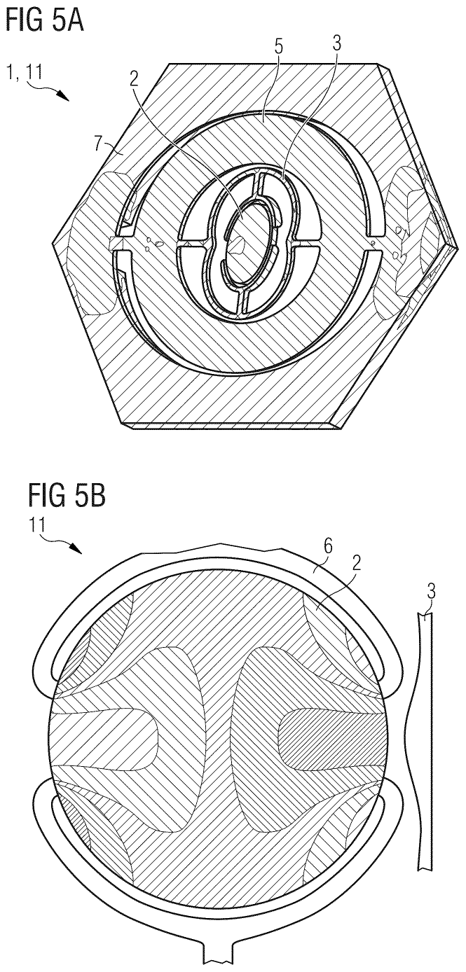

FIG. 5A shows a schematic representation of a tensile stress in a material of a microelectromechanical mirror 1 according to the first exemplary embodiment. In particular, the tensile stress is shown at a maximum deflection angle of the mirror element 2 of 16.5° about the long axis 31 in the first oscillation mode 11. A maximum tensile stress is approximately 2.4 GPa.

FIG. 5B shows a schematic representation of a deformation of the main extension plane 21 of the mirror element 2 of a microelectromechanical mirror 1 according to the first exemplary embodiment. In particular, the deformation is shown in a direction perpendicular to the main extension plane 21 at a maximum deflection angle of the mirror element 2 of 16.5° about the long axis 31 in the first oscillation mode 11. A maximum deformation is approximately ±310 nm at the edge of the mirror element 2.

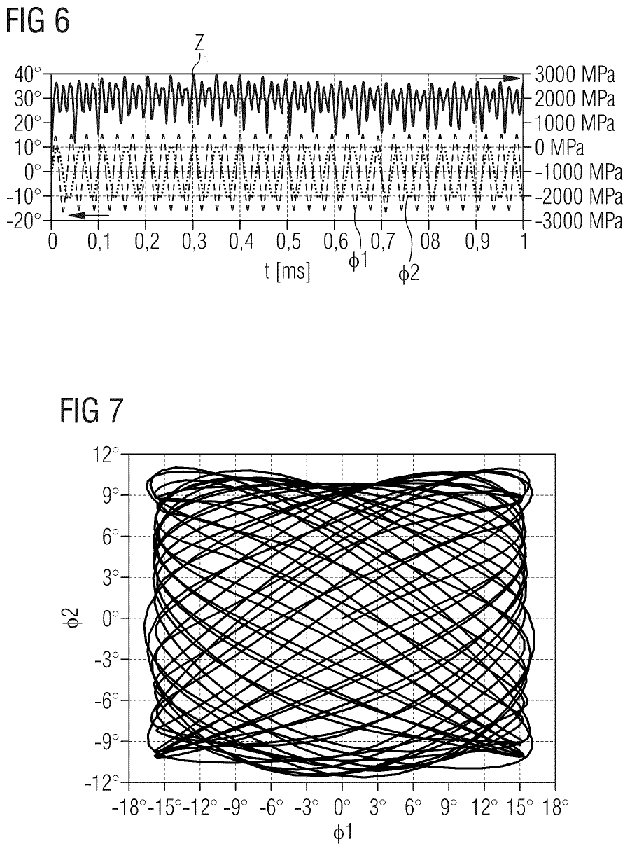

FIG. 6 shows deflection angles φ1, φ2 of a mirror element 2 about the long axis 31 and about the short axis 32, respectively, as well as a maximum tensile stress Z in the material of a microelectromechanical mirror 1 according to the first exemplary embodiment during an oscillation of the mirror element 2 corresponding to the first and second oscillation modes 11, 12 as a function of time t.

FIG. 7 shows deflection angles φ1, φ2 of a mirror element 2 about the long axis 31 and about the short axis 32 of a microelectromechanical mirror 1 according to the first exemplary embodiment, in which the first oscillation mode 11 and the second oscillation mode 12 are driven simultaneously. In particular, the deflection of the mirror as a function of time describes a Lissajous figure.

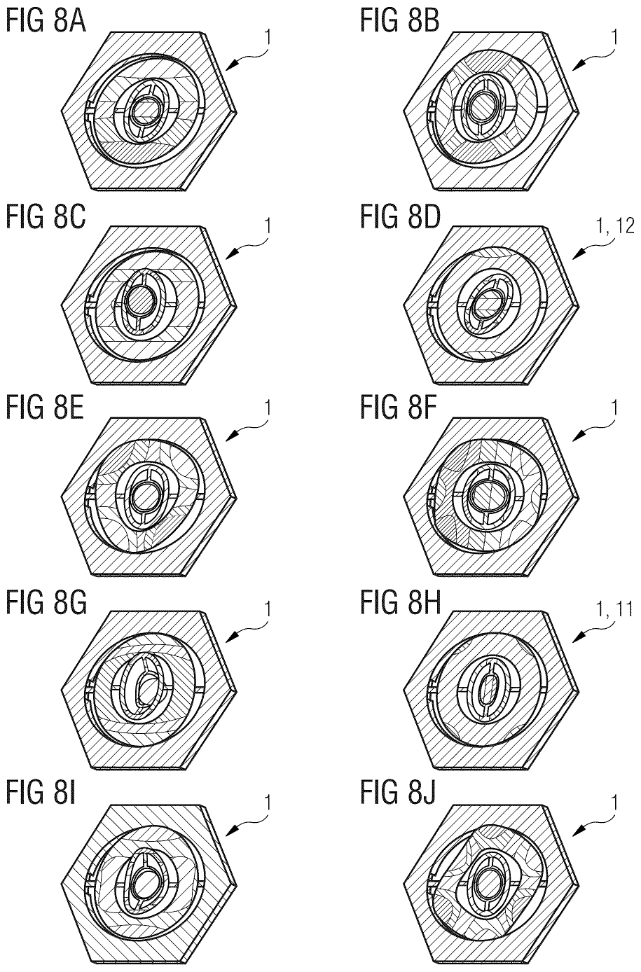

FIGS. 8A to 8J show numerical simulations of different oscillation modes of a microelectromechanical mirror 1 according to the second exemplary embodiment. In particular, the deflection of different elements of the microelectromechanical mirror 1 at a certain point in time is shown exaggeratedly large for better visualization. The resonance frequencies fR of the oscillation modes shown are listed in the following table:

| FIG. | 8A | 8B | 8C | 8D | 8E |
|---|---|---|---|---|---|
| fR [kHz] | 3.08 | 3.85 | 7.67 | 9.20 | 12.99 |
| FIG. | 8F | 8G | 8H | 8I | 8J |
| fR [kHz] | 14.27 | 18.76 | 20.29 | 23.31 | 29.37 |

The oscillation mode in FIG. 8D corresponds to the second oscillation mode 12 of the second exemplary embodiment, in which the mirror element 2 together with the torsional suspension 3 performs a rotational oscillation about the short axis 32.

The oscillation mode in FIG. 8H corresponds to the first oscillation mode 11 of the second exemplary embodiment, in which the mirror element 2 performs a rotational oscillation about the long axis 31, while the torsional suspension 3 performs a bending movement, in particular.

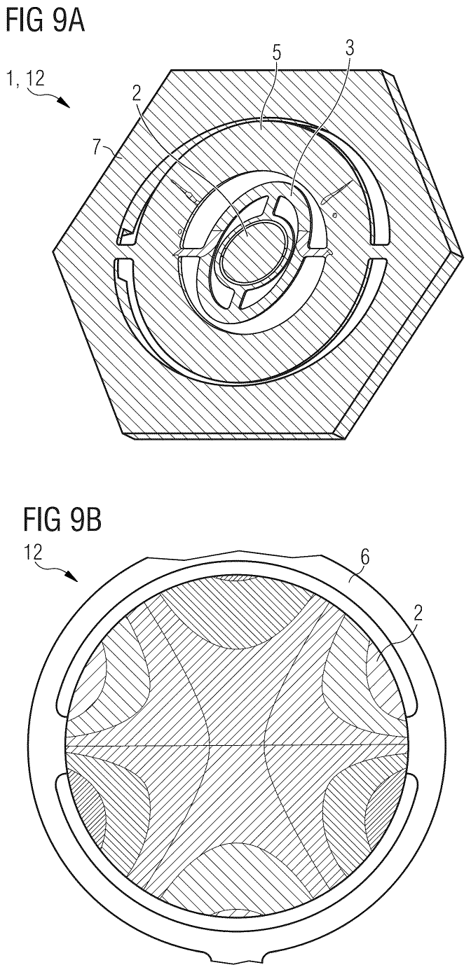

FIG. 9A shows a schematic representation of a tensile stress in a material of a microelectromechanical mirror 1 according to the second exemplary embodiment. In particular, the tensile stress is shown at a maximum deflection angle of the mirror element 2 of 11° about the short axis 32 in the second oscillation mode 12. A maximum tensile stress is approximately 1.0 GPa.

FIG. 9B shows a schematic representation of a deformation of the main extension plane 21 of the mirror element 2 of a microelectromechanical mirror 1 according to the second exemplary embodiment. In particular, the deformation is shown in a direction perpendicular to the main extension plane 21 at a maximum deflection angle of the mirror element 2 of 11° about the short axis 32 in the second oscillation mode 12. A maximum deformation is approximately ±230 nm at the edge of the mirror element 2.

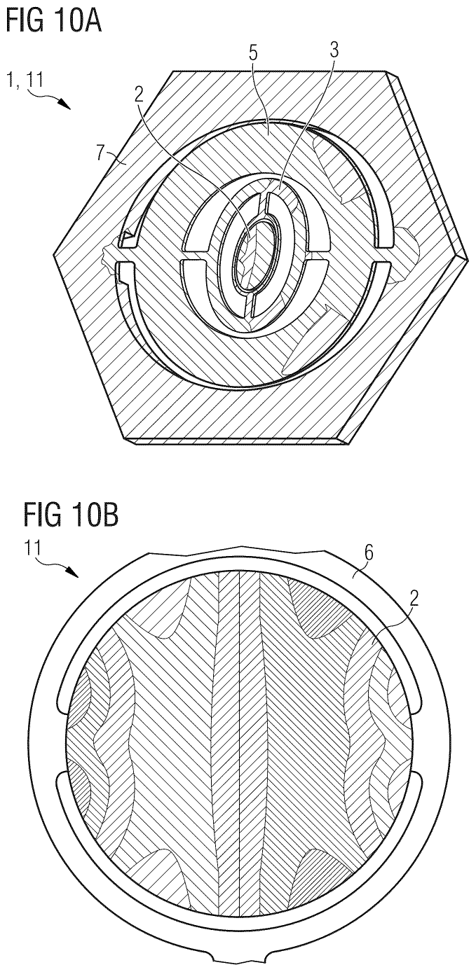

FIG. 10A shows a schematic representation of a tensile stress in a material of a microelectromechanical mirror 1 according to the second exemplary embodiment. In particular, the tensile stress is shown at a maximum deflection angle of the mirror element 2 of 16.5° about the long axis 31 in the first oscillation mode 11. A maximum tensile stress is approximately 1.5 GPa.

FIG. 10B shows a schematic representation of a deformation of the main extension plane 21 of the mirror element 2 of a microelectromechanical mirror 1 according to the second exemplary embodiment. In particular, the deformation is shown in a direction perpendicular to the main extension plane 21 at a maximum deflection angle of the mirror element 2 of 16.5° about the long axis 31 in the first oscillation mode 11. A maximum deformation is approximately ±430 nm at the edge of the mirror element 2.

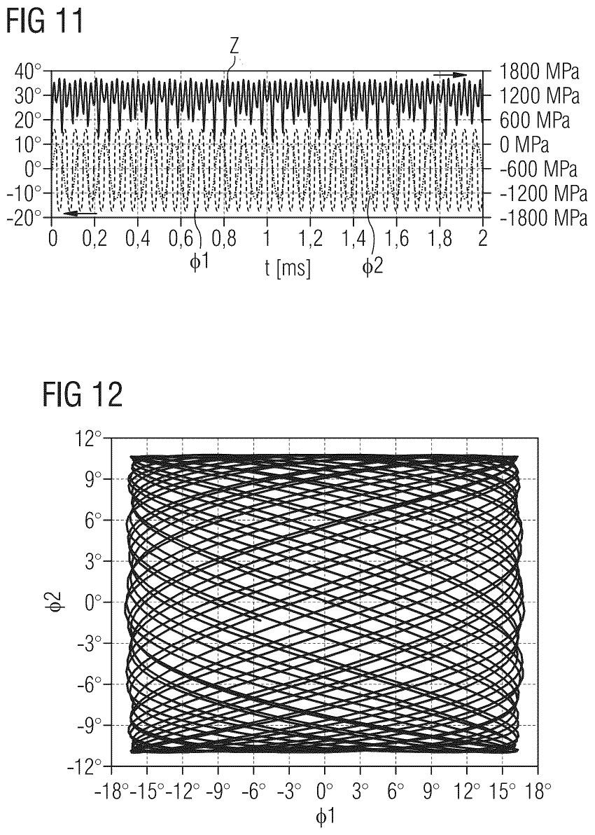

FIG. 11 shows deflection angles φ1, φ2 of a mirror element 2 about the long axis 31 and about the short axis 32, respectively, as well as a maximum tensile stress Z in the material of a microelectromechanical mirror 1 according to the second exemplary embodiment during an oscillation of the mirror element 2 corresponding to the first and second oscillation modes 11, 12 as a function of time t.

FIG. 12 shows deflection angles φ1, φ2 of a mirror element 2 about the long axis 31 and about the short axis 32 of a microelectromechanical mirror 1 according to the second exemplary embodiment, in which the first oscillation mode 11 and the second oscillation mode 12 are driven simultaneously. In particular, the deflection of the mirror as a function of time describes a Lissajous figure.

FIG. 13 shows a schematic cross-sectional view of a microelectromechanical mirror 1 according to the second exemplary embodiment. In particular, a cross-section parallel and offset to the short axis 32 is shown. The mirror element 2, the connection element 6, the torsional suspension 3, the drive ring 5 and the frame 7 comprise a common substrate 8 and are integrally formed in one piece. The substrate 8 has a constant thickness. A metallic reflective layer 22 is arranged on the main surface 21 of the mirror element 2.

On the drive ring 5, the piezoelectric layer 50 is arranged between a first electrode 51 and a second electrode 52. A sensor element 9 is arranged on the torsional suspension 3, which comprises a piezoelectric layer 90 between a first electrode 91 and a second electrode 92.

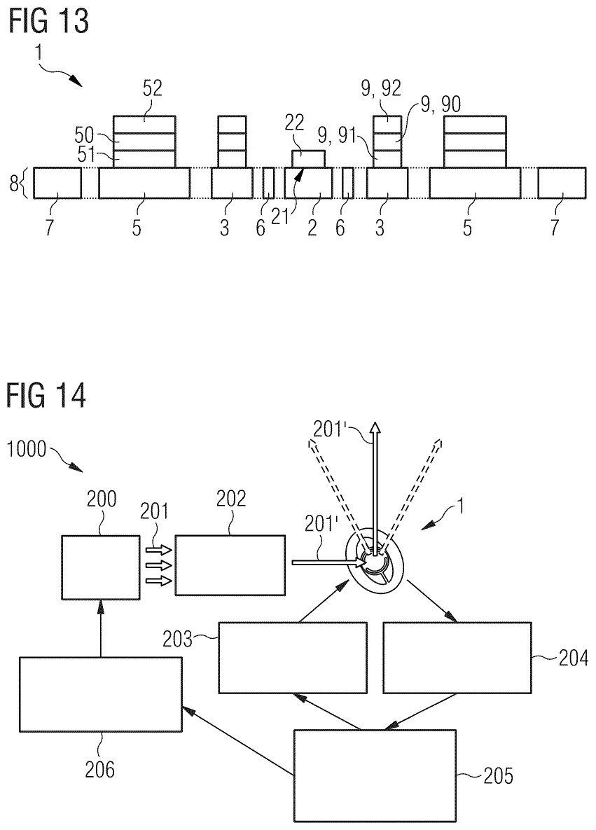

FIG. 14 shows a schematic representation of a projection device 1000 according to an exemplary embodiment, which comprises a microelectromechanical mirror 1 according to the previous description. Furthermore, the projection device comprises a laser light source 200 which emits laser light 201 during operation.

For example, the laser light source 200 can be a so-called RGB light source, which can emit red, green and blue laser light. For this purpose, the laser light source 200 can, for example, have three laser diodes or laser diode groups that can be modulated accordingly. The laser light beams can, for example, be superimposed in a beam combiner 202, so that a beam of combined laser light 201′ can be irradiated onto the piezoelectric mirror component 100 and reflected by it into the desired image area. The laser light source 200 can, for example, be controlled via laser control electronics 206, for example to modulate the amplitude of the laser light 201, 201′ over time.

The microelectromechanical mirror 1 can be controlled via mirror control electronics 203, for example to generate the desired Lissajous figure with which the desired image area can be scanned. Furthermore, sensor electronics 204 can be provided in order to detect the position and/or the frequencies of the mirror element 2 of the microelectromechanical mirror 1, preferably in real time. In addition, image processing electronics 205 may be provided, for example to control the entire image display. In particular, this can correspond to the conversion of image or film information into control signals for the laser light source 200 and the microelectromechanical mirror 1, including the temporal synchronization between the position of the mirror element 2 and the amplitudes of the laser light 201, 201′.

The invention is not limited to the exemplary embodiments by the description based thereon. Rather, the invention includes any new feature as well as any combination of features, which includes, in particular, any combination of features in the patent claims, even if this feature or combination itself is not explicitly stated in the patent claims or embodiments.

1.-38. (canceled)

39. A microelectromechanical mirror comprising:
a mirror element; and
a torsional suspension, which surrounds the mirror element and which is connected to the mirror element via two first torsion spring elements.

40. The microelectromechanical mirror according to claim 39, further comprising:
a piezoelectric drive ring, which surrounds the torsional suspension and which is connected to the torsional suspension via two second torsion spring elements.

41. The microelectromechanical mirror according to claim 40, further comprising a piezoelectric layer disposed on the drive ring.

42. The microelectromechanical mirror according to claim 41, wherein the piezoelectric layer is arranged between a first electrode and a second electrode.

43. The microelectromechanical mirror according to claim 42, wherein the second electrode comprises a plurality of drive regions that are separated from each other.

44. The microelectromechanical mirror according to claim 40, wherein the two second torsion spring elements are arranged on opposite sides of the torsional suspension.

45. The microelectromechanical mirror according to claim 40, wherein the drive ring is circular ring-shaped.

46. The microelectromechanical mirror according to claim 40, wherein the drive ring is arranged in a main extension plane of the mirror element in a rest position.

47. The microelectromechanical mirror according to claim 40, wherein the torsional suspension has an elongated shape with a long axis and a short axis perpendicular thereto.

48. The microelectromechanical mirror according to claim 47, wherein the first torsion spring elements are arranged along the long axis.

49. The microelectromechanical mirror according to claim 47, wherein the second torsion spring elements are arranged along the short axis.

50. The microelectromechanical mirror according to claim 47, wherein the mirror element and the first torsion spring elements are connected to each other via a connection element.

51. The microelectromechanical mirror according to claim 50, wherein the connection element has a circular ring shape and is connected to the mirror element via two suspension points.

52. The microelectromechanical mirror according to claim 51, wherein the two suspension points are arranged on opposite sides of the mirror element along the short axis.

53. The microelectromechanical mirror according to claim 50, wherein the connection element comprises two separate arc-shaped segments that are connected to one of the two first torsion spring elements, respectively.

54. The microelectromechanical mirror according to claim 53, wherein each of the arc-shaped segments is connected to the mirror element via two suspension points.

55. The microelectromechanical mirror according to claim 47, wherein the drive ring is connected to a frame via two third torsion spring elements.

56. The microelectromechanical mirror according to claim 55, wherein the two third torsion spring elements are arranged on opposite sides of the drive ring along the short axis.

57. The microelectromechanical mirror according to claim 55, wherein the mirror element, the torsional suspension, the drive ring, the frame and the torsion spring elements are integrally formed as a one-piece component.

58. The microelectromechanical mirror according to claim 57, wherein all elements of the one-piece component comprise a common substrate that has a constant thickness.

59. The microelectromechanical mirror according to claim 55, further comprising at least one sensor element configured for determining a deflection and/or a frequency of an oscillation of the mirror element, wherein the at least one sensor element is arranged on the drive ring and/or on the frame.

60. The microelectromechanical mirror according to claim 59, wherein the at least one sensor element comprises a piezoelectric layer.

61. The microelectromechanical mirror according to claim 60, wherein the piezoelectric layer is arranged between two electrodes.

62. The microelectromechanical mirror according to claim 47, wherein the torsional suspension is configured for linearizing an oscillation mode about the long axis.

63. A method of operating the microelectromechanical mirror according to claim 47, the method comprising:
setting the mirror element into a first oscillation mode by a first electrical alternating current signal with a first frequency acting on first drive regions of the drive ring.

64. The method according to claim 63, wherein the torsional suspension is set into a second oscillation mode a second electrical alternating current signal with a second frequency acting on second drive regions of the drive ring.

65. The method according to claim 64,
wherein the first oscillation mode comprises a rotation of the mirror element about the long axis, and
wherein the second oscillation mode comprises a rotation of the mirror element about the short axis.

66. The method according to claim 65, wherein the first oscillation mode and/or the second oscillation mode are resonantly excited.

67. The method according to claim 63, wherein a movement of the drive ring in the first oscillation mode and/or in a second oscillation mode has an amplitude that is at most one fifth of an amplitude of a movement of the mirror element.

68. The method according to claim 63, wherein a resonance frequency of the first oscillation mode is larger than a resonance frequency of a second oscillation mode by at least a factor of 1.3.

69. The method according to claim 63, wherein the first oscillation mode and/or a second oscillation mode are operated in a harmonic range.

70. The method according to claim 63, wherein a second oscillation mode is a torsional oscillation of the torsional suspension with the mirror element about the short axis, and wherein the first oscillation mode is a combination of a torsional oscillation of the mirror element about the long axis and a bending movement of the torsional suspension.

71. The microelectromechanical mirror according to claim 39, wherein the two first torsion spring elements are arranged on opposite sides of the mirror element.

72. The microelectromechanical mirror according to claim 39, wherein the torsional suspension has an elliptical ring shape or the shape of an indented oval ring.

73. The microelectromechanical mirror according to claim 39, wherein the torsional suspension has no piezoelectric drive elements and/or consists of a substrate.

74. The microelectromechanical mirror according to claim 39, further comprising at least one sensor element configured for determining a deflection and/or a frequency of an oscillation of the mirror element, wherein the at least one sensor element is arranged on the torsional suspension.

75. A projection device comprising:
a laser light source; and
the microelectromechanical mirror according to claim 39.

76. A method of operating the microelectromechanical mirror according to claim 39, the method comprising:
projecting information onto a surface for head-up display, for matrix illumination, for LIDAR applications, for hologram projectors, for VR glasses, or for AR glasses.
